(19) United States
(12) Patent Application Publication
(10) Pub. No.: US 2010/0038719 A1
(43) Pub. Date: Feb. 18, 2010

(54) Semiconductor apparatuses and methods of manufacturing the same

(75) Inventors: Won-Joo Kim, Hwaseong-si (KR); Tae-hee Lee, Yongin-si (KR); Yoon-dong Park, Suwon-si (KR); Sang-moo Choi, Suwon-si (KR); Dae-kll Cha, Seoul (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/461,131

(22) Filed: Jul. 31, 2009

(30) Foreign Application Priority Data
Aug. 12, 2008 (KR) 10-2008-0090489

(51) Int. Cl. H01L 27/088; H01L 21/8234

(52) U.S. Cl. 257/368; 438/151; 257/E27.06; 257/E21.616

(57) ABSTRACT

Disclosed are semiconductor apparatuses and methods of fabricating the same. According to the methods, the number of operations for fabricating the semiconductor apparatuses having a plurality of layers may be the same as the number of operations for fabricating a semiconductor apparatus having one layer. The semiconductor apparatuses may include first active regions extending in the same direction, in parallel, separated from each other and including first and second impurity doped regions on opposite ends of the first active regions from each other. The semiconductor apparatuses may further include second active regions on a layer above the first active regions, extending in the same direction as the first active regions, separated from each other, in parallel, and including first and second impurity doped regions on opposite ends of the second active regions from each other.

### PRIORITY STATEMENT

This application claims priority under 35 U.S.C. §119 to Korean Patent Application No. 10-2008-0090489, filed on Sep. 12, 2008, in the Korean Intellectual Property Office (KIPO), the entire contents of which is incorporated herein by reference.

### BACKGROUND

1. Field

Example embodiments relate to semiconductor apparatuses and methods of manufacturing the same, and more particularly to multi-layer semiconductor apparatuses and methods of manufacturing the same.

2. Description of the Related Art

A conventional 1T DRAM is a memory device that uses one transistor (1T) and does not include a capacitor (1C). The 1T DRAM has recently become widely used. The 1-T DRAM may have an improved sensing margin and may be manufactured using simple manufacturing operations. Semiconductor devices utilizing 1T DRAM may include multi-layer configurations (e.g., 1T DRAM stacked vertically). However, the number of manufacturing operations may increase for multi-layer devices in proportion to the number of layers. Furthermore, the resultant junction profiles for each of the layers may be different, causing inconsistent retention characteristics of the semiconductor apparatus.

### SUMMARY

Example embodiments disclose semiconductor apparatuses and methods of fabricating the same. According to the methods, the number of operations for fabricating a semiconductor apparatus having a plurality of layers may be the same as the number of operations for fabricating a semiconductor apparatus having one layer.

According to example embodiments, there is provided a semiconductor apparatus including an array of active regions, the array of active regions including individual active regions arranged in a plurality of rows and a plurality of columns, the active regions being separated from each other and extending in parallel in a same direction such that there are row spaces between the active regions arranged in each row and there are column spaces between the active regions arranged in each column, each active region including a first impurity doped region at a first end and a second impurity doped region at a second end, where the first end and the second end are opposite to each other.

The semiconductor apparatus may further include a gate pattern architecture including one or more column gate electrodes connected to one or more array gate electrodes, wherein each column gate electrode extends vertically along an associated column space, each array gate electrode extends parallel to the plurality of rows, and the gate pattern architecture is formed as a single body.

The column gate electrodes may be formed in every column space between the individual active regions, in less than every column space between the individual active regions and/or adjacent to the individual active regions.

The first and second impurity doped regions may be shallowly formed at first and second ends of the individual active regions such that the first and second impurity doped regions and the gate pattern do not overlap.

According to example embodiments, there is provided a method of fabricating a semiconductor apparatus, the method including dividing an alternately stacked plurality of insulating layers and plurality of active layers into an array of active regions including individual active regions formed in a plurality of rows and a plurality of columns such that there are column spaces separating the plurality of columns, the individual active regions extending in parallel in a same direction, each active region having side surfaces, first end surfaces, and second end surfaces, the first end surfaces opposite the second end surfaces; encapsulating the array of active regions with an array insulation layer; partially patterning the array insulation layer to expose the side surfaces; forming a gate pattern architecture including forming one or more column gate electrodes and one or more array gate electrodes, each of the column gate electrodes associated with one of the plurality of columns and formed on one or more of the side surfaces, and the array gate electrodes formed parallel to the plurality of rows; partially patterning the array insulation layer to expose the first and second end surfaces; and forming first and second impurity doped regions at the first and second end surfaces.

### BRIEF DESCRIPTION OF THE DRAWINGS

Example embodiments will be more clearly understood from the following brief description taken in conjunction with the accompanying drawings. FIGS. 1-13 represent non-limiting, example embodiments as described herein.

FIG. 1 is a cross-sectional view of a conventional semiconductor apparatus;

FIGS. 2-3 are perspective views of the interior of a semiconductor apparatus according to an example embodiment;

FIG. 4 is a circuit diagram of a semiconductor apparatus according to FIGS. 2-3;

FIGS. 5-6 are perspective views of the interior of a semiconductor apparatus according to an example embodiment;

FIG. 7 is a circuit diagram of a semiconductor apparatus according to FIGS. 5-6; and

FIGS. 8-13 are perspective views of a method of fabricating a semiconductor apparatus according to an example embodiment.

It should be noted that these Figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION OF EXAMPLE EMBODIMENTS

Example embodiments will now be described more fully with reference to the accompanying drawings, in which example embodiments are shown. Example embodiments may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

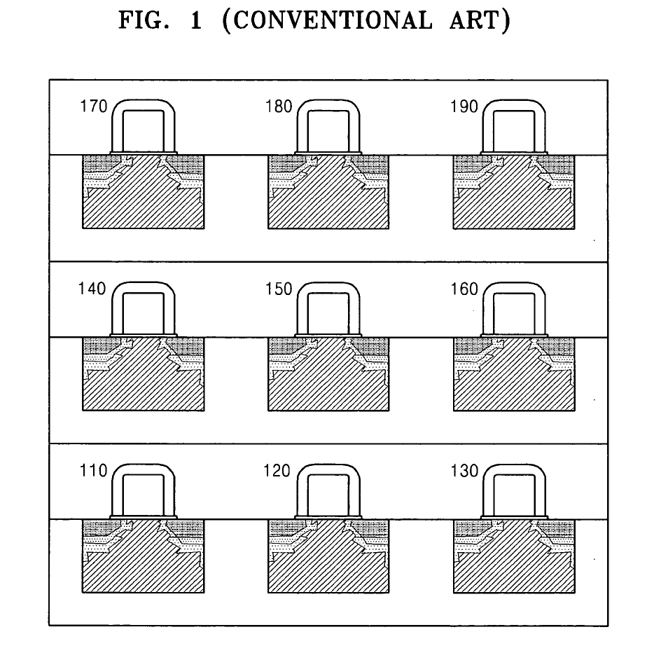

FIG. 1 is a cross-sectional view of a conventional semiconductor apparatus. Referring to FIG. 1, the semiconductor apparatus includes nine 1T-DRAM cells that are disposed in three layers. In a method of manufacturing the conventional semiconductor apparatus shown in FIG. 1, the number of operations may increase in proportion to the number of layers. Furthermore, the junction profile of each of the layers may be different from each other and as a result, retention characteristics of the semiconductor apparatus may be inconsistent.

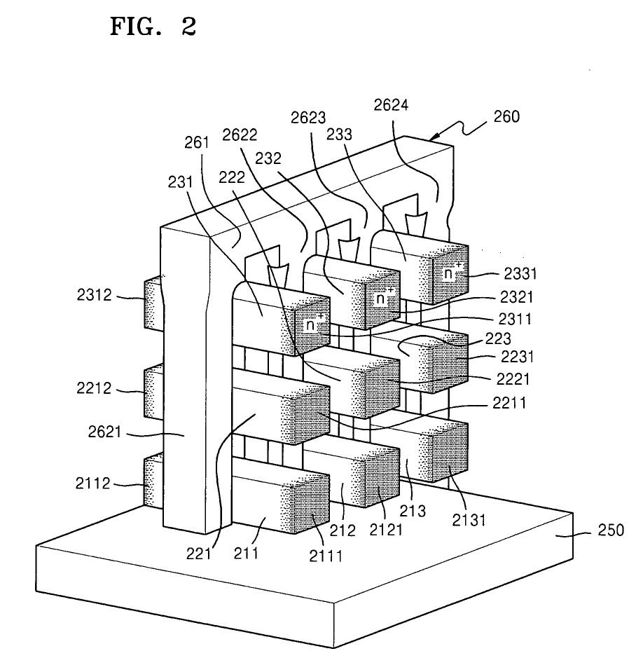

FIG. 2 is a first perspective view of the interior of a semiconductor apparatus according to an example embodiment. Referring to FIG. 2, the semiconductor apparatus may include an array of active regions including individual active regions arranged in a plurality of rows and a plurality of columns. Individual active regions 211, 212, and 213, may be arranged in a first row, individual active regions 221, 222, and 223, may be arranged in a second row, and individual active regions 231, 232, and 233, may be arranged in a third row. The rows of individual active regions may be arranged in layers (e.g., vertically arranged) on a substrate region 250. Although FIG. 2 shows a specific number of active regions, one having ordinary skill in the art will appreciate that the specific number of active regions are shown for explanatory purposes and example embodiments are not so limited.

The individual active regions 211, 212, and 213, of the first row of individual active regions may extend in the same direction, may be separated from each other and may be in parallel. The individual active regions 221, 222, and 223, of the second row of individual active regions may be disposed on a layer above a layer on which the first row of individual active regions 211, 212, and 213, are disposed. The individual active regions 221, 222, and 223, of the second row of individual active regions may extend in the same direction as the individual active regions 211, 212, and 213, of the first row of individual active regions and may be separated from each other and may be in parallel. The individual active regions 231, 232, and 233, of the third row of individual active regions may be disposed on a layer above a layer on which the individual active regions 221, 222, and 223, of the second row of individual active regions are disposed. The individual active regions 231, 232, and 233, of the third row of individual active regions may extend in the same direction as the individual active regions 221, 222, and 223, of the second row of individual active regions, may be separated from each other and may be in parallel. The first row, the second row and the third row may be separated by row spaces.

Individual active regions 211, 221, and 231 may be arranged in a first column, individual active regions 212, 222, and 232 may be arranged in a second column, and individual active regions 213, 223, and 233, may be arranged in a third column. Individual active regions 211, 221 and 231 may be arranged separated from each other and may be in parallel. Individual active regions 212, 222 and 232 may be arranged separated from each other and may be in parallel. Individual active regions 213, 223 and 233 may be arranged separated from each and may be in parallel. The first column, the second column and the third column may be separated by column spaces.

Each of the individual active regions 211, 212, and 213, of the first row may include first and second impurity doped regions. The individual active region 211 may include first and second impurity doped regions 2111 and 2112 corresponding to first and second ends of the individual active region 211. The first and second ends may be opposite ends of the individual active region 211. The individual active region 212 may include a first impurity doped region 2121 and a second impurity doped region (not shown) corresponding to first and second ends of the individual active region 212. The first and second ends may be opposite ends of the individual active region 212. The individual active region 213 may include a first impurity doped region 2131 and a second impurity doped region (not shown) corresponding to first and second ends of the individual active region 213. The first and second ends may be opposite ends of the individual active region 213.

Each of the individual active regions 221, 222, and 223, of the second row may include first and second impurity doped regions. The individual active region 221 may include first and second impurity doped regions 2211 and 2212 corresponding to first and second ends of the individual active region 221. The first and second ends may be opposite ends of the individual active region 221. The individual active region 222 may include a first impurity doped region 2221 and a second impurity doped region (not shown) corresponding to first and second ends of the individual active region 222. The first and second ends may be opposite ends of the individual active region 222. The individual active region 223 may include a first impurity doped region 2231 and a second impurity doped region (not shown) corresponding to first and second ends of the individual active region 223. The first and second ends may be opposite ends of the individual active region 223.

Each of the individual active regions 231, 232, and 233, of the third row may include first and second impurity doped regions. The individual active region 231 may include first and second impurity doped regions 2311 and 2312 corresponding to first and second ends of the individual active region 231. The first and second ends may be opposite ends of the individual active region 231. The individual active region 232 may include a first impurity doped region 2321 and a second impurity doped region (not shown) corresponding to first and second ends of the individual active region 232. The first and second ends may be opposite ends of the individual active region 232. The individual active region 233 may include a first impurity doped region 2331 and a second impurity doped region (not shown) corresponding to first and second ends of the individual active region 233. The first and second ends may be opposite ends of the individual active region 233.

The first and second impurity doped regions 2111, 2112, 2121, 2131, 2211, 2212, 2221, 2231, 2311, 2312, 2321, 2331 and the second impurity doped regions that are not shown, may be formed to a shallow depth on the first and second ends of the individual active regions 211, 212, 213, 221, 222, 223, 231, 232, and 233. The first impurity doped regions 2111, 2121, 2131, 2211, 2221, 2231, 2311, 2321, and 2331 may include the entire first end surface of the individual active regions 211, 212, 213, 221, 222, 223, 231, 232, and 233, extending to portions of the top, bottom and side surfaces of the individual active regions 211, 212, 213, 221, 222, 223, 231, 232, and 233 adjacent to the first end surface. The second impurity doped regions 2112, 2212, 2312, and the second impurity doped regions that are not shown, may include the entire second end surface of the individual active regions 211, 212, 213, 221, 222, 223, 231, 232, and 233 and may extend to portions of the top, bottom and side of the individual active regions 211, 212, 213, 221, 222, 223, 231, 232, and 233 adjacent to the second end surface.

The horizontal length of the first and second impurity doped regions 2111, 2112, 2121, 2131, 2211, 2212, 2221, 2231, 2311, 2312, 2321, 2331 and the second impurity doped regions that are not shown, may be shorter than the vertical length of the same. Because the first and second impurity doped regions 2111, 2112, 2121, 2131, 2211, 2212, 2221, 2231, 2311, 2312, 2321, 2331 and the second impurity doped regions that are not shown, may be formed along two opposite ends of the individual active regions 211, 212, 213, 221, 222, 223, 231, 232, and 233, the vertical length of the first and second impurity doped regions 2111, 2112, 2121, 2131, 2211, 2212, 2221, 2231, 2311, 2312, 2321, 2331 and the second impurity doped regions that are not shown, may be about the same as that of the individual active regions 211, 212, 213, 221, 222, 223, 231, 232, and 233. In contrast, the horizontal length of the first and second impurity doped regions 2111, 2112, 2121, 2131, 2211, 2212, 2221, 2231, 2311, 2312, 2321, 2331 and the second impurity doped regions that are not shown, may be shorter than the vertical length of the first and second impurity doped regions 2111, 2112, 2121, 2131, 2211, 2212, 2221, 2231, 2311, 2312, 2321, 2331 and the second impurity doped regions that are not shown, or the vertical length of the individual active regions 211, 212, 213, 221, 222, 223, 231, 232, and 233. An interval (e.g., horizontal distance) between the first and second impurity doped regions may be equal to or greater than 2.0 F, where F is the minimum resolvable line width of a the active region array.

The horizontal length of the first and second impurity doped regions 2111, 2112, 2121, 2131, 2211, 2212, 2221, 2231, 2311, 2312, 2321, 2331 and the second impurity doped regions that are not shown, may increase in a vertical direction. For example, the horizontal length at upper vertical positions along the first and second impurity doped regions 2111, 2112, 2121, 2131, 2211, 2212, 2221, 2231, 2311, 2312, 2321, 2331 and the second impurity doped regions that are not shown, may be shorter than the horizontal length at lower vertical positions along the same. In the first and second impurity doped regions 2111, 2112, 2121, 2131, 2211, 2212, 2221, 2231, 2311, 2312, 2321, 2331 and the second impurity doped regions that are not shown, impurities may be uniformly distributed along the vertical axis and/or a ratio of maximum impurity distribution with respect to minimum impurity distribution may be less than or equal to 10:1. Accordingly, impurities may be distributed in relative uniformity along the vertical axis in the first and second impurity doped regions 2111, 2112, 2121, 2131, 2211, 2212, 2221, 2231, 2311, 2312, 2321, 2331 and the second impurity doped regions that are not shown.

A semiconductor apparatus according to example embodiments may further include a gate pattern architecture 260. The gate pattern architecture 260 may include array gate electrodes 261 and column gate electrodes 2621, 2622, 2623 and 2624. The array gate electrodes 261 may extend horizontally across and/or above the individual active regions. For example, the array gate electrodes may extend horizontally above the individual active regions 231, 232, and 233. The column gate electrodes 2621, 2622, 2623 and 2624, may extend vertically, adjacent to and/or between the individual active regions 211, 212, and 213, adjacent to and/or between the individual active regions 221, 222, and 223, and adjacent to and/or between the individual active regions 231, 232, and 233. The column gate electrodes 2621, 2622, 2623 and 2624, may be on the side surfaces of the individual active regions. A gate insulation layer may be interposed between the column gate electrodes and the side surfaces.

If the column gate electrodes 2621, 2622, 2623, and 2624, extend vertically between the individual active regions, they may extend through column spaces. Each column gate electrode 2621, 2622, 2623, and 2624, may or may not be associated with a unique column space. The column gate electrodes 2621, 2622, 2623, and 2624, may be formed in every column space between the individual active regions 211, 212, and 213, between the individual active regions 221, 222, and 223, and between the individual active regions 231, 232, and 233. For example, column gate electrode 2622 may extend vertically between individual active regions 211 and 212, between individual active regions 221 and 222, and between third active regions 231 and 232. The array gate electrode 261 and the column gate electrodes 2621, 2622, and 2623 may be a single body.

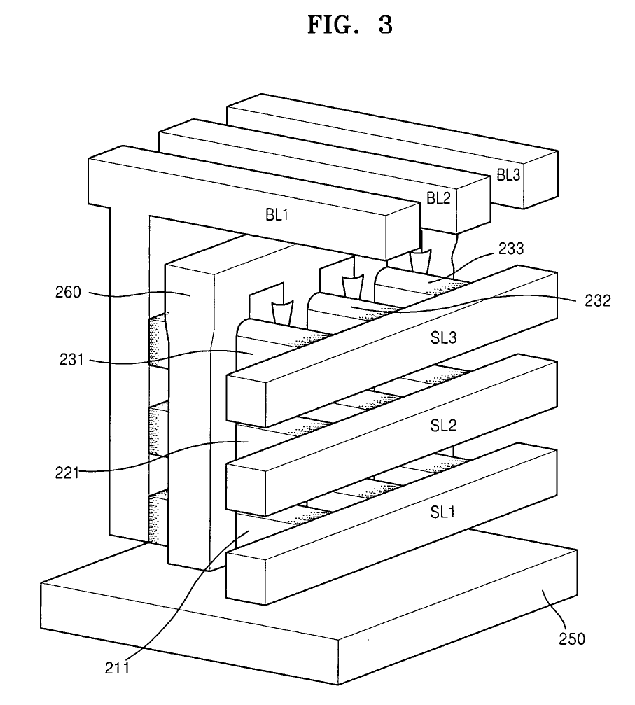

FIG. 3 is a perspective view of the interior of a semiconductor apparatus according to an example embodiment. Referring to FIG. 3, FIG. 3 shows the semiconductor apparatus of FIG. 2, further including first through third source lines SL1, SL2, and SL3 and first through third bitlines BL1, BL2, and BL3.

The first through third source lines SL1, SL2, and SL3 may extend horizontally and may be connected to first impurity doped regions at first end surfaces of the first through third rows of individual active regions. For example, the first source line SL1 may be connected to first impurity doped regions 2111, 2121 and 2131 at first end surfaces of the first row of individual active regions 211, 212, and 213. The second source line SL2 may be connected to first impurity doped regions 2211, 2221 and 2231 at first end surfaces of the second row of individual active regions 221, 222, and 223. The third source line SL3 may be connected to first impurity doped regions 2311, 2321, and 2331 at first end surfaces of the third row of individual active regions 231, 232, and 233.

The first through third bitlines BL1, BL2, and BL3 may extend vertically and may be connected to second impurity doped regions at second end surfaces of one of the individual active regions in each row. The first through third bitlines BL1, BL2, and BL3 may extend vertically and may be connected to second impurity doped regions at second end surfaces of one of the individual active regions 211, 212, and 213, one of the individual active regions 221, 222, and 223, and one of the individual active regions 231, 232, and 233. For example, the first bitline BL1 may extend vertically across and may be connected to the second impurity region 2112 at the second end of the individual active region 211, the second impurity region 2212 at the second end of the individual active region 221 and the second impurity region 2312 at the second end of the individual active region 231. The second and third bitlines BL2 and BL3 are connected to impurity doped regions of the active regions in a similar manner. (Referring to FIGS. 2-3, second end surfaces of impurity doped regions corresponding to BL2 and BL3 are not shown.)

Although FIGS. 2-3 show three layers, each including three active regions, for a total of nine active regions, example embodiments are not limited thereto. For example, a semiconductor apparatus according to example embodiments may include two layers, including two active regions per layer, for a total of 4 active regions, that may include two bitlines and two source lines. The number of layers or active regions may be chosen to obtain a desired integration density and may also include more than three layers. Therefore, a semiconductor apparatus according to example embodiments may, for example, include n layers, including j active regions per layer, for a total of j times n active regions, that may include j bitlines and n source lines, where n and j may be natural numbers greater than 0.

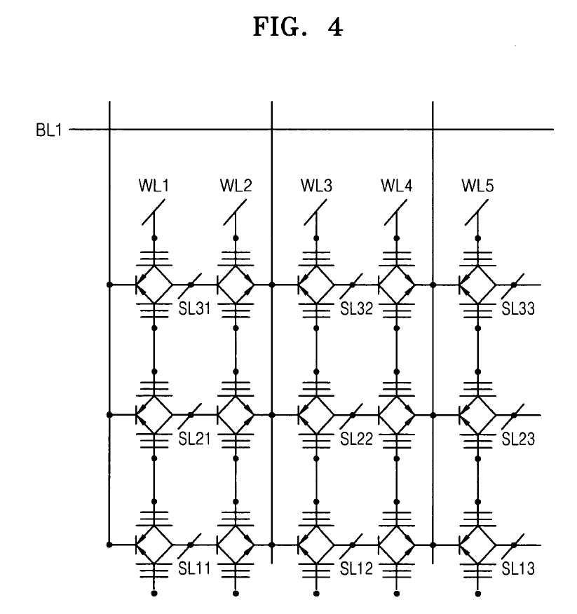

FIG. 4 is a circuit diagram of a semiconductor apparatus according to an example embodiment. Referring to FIG. 4, there may be one bitline BL1 and a plurality of semiconductor devices connected to a plurality of wordlines WL1 through WL5 and to a plurality of source lines SL11 through SL33. One wordline (e.g., WL1) from among the wordlines WL1 through WL5 may correspond to the gate pattern architecture 260 shown in FIGS. 2-3. The bitline BL1 may correspond to one bitline (e.g. BL1) from among the bitlines BL1 through BL3 shown in FIG. 3. Three source lines (e.g., SL11, SL21, and SL31) from among the source lines SL11 through SL33 may correspond to the source lines SL1, SL2, and SL3 shown in FIG. 3.

The semiconductor apparatus disclosed in example embodiments according to FIGS. 2-4 may be a 1T-DRAM. The gate pattern architecture 260 may be a base region, and the first and second impurity doped regions may be emitter regions or source regions.

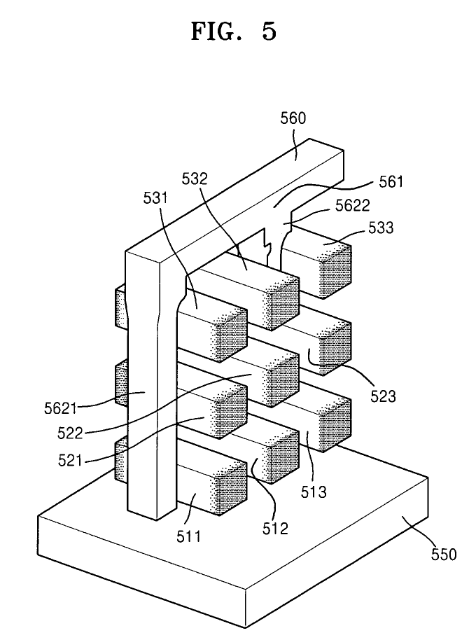

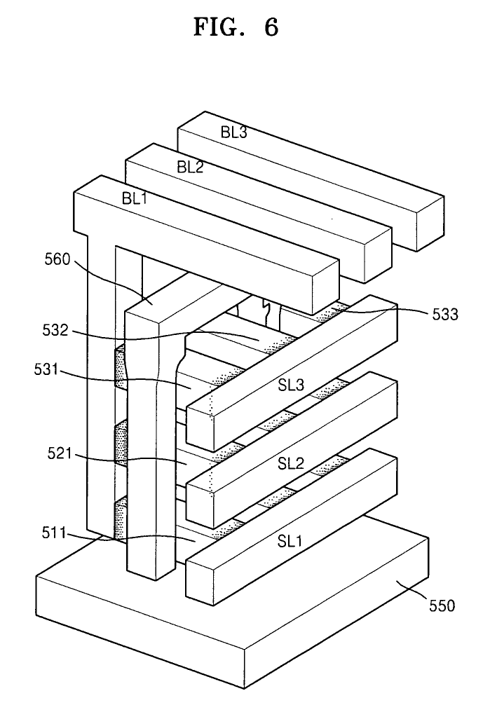

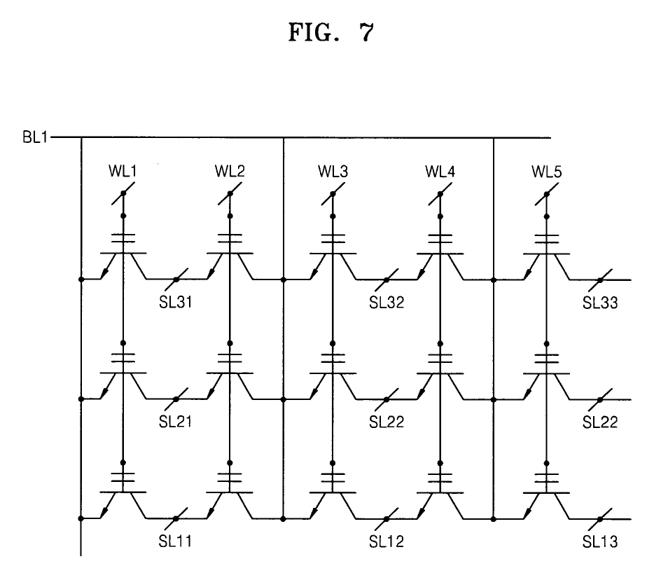

FIGS. 5-6 are perspective views of the interior of a semiconductor apparatus according to an example embodiment. FIG. 7 is a circuit diagram of the semiconductor apparatus according to the example embodiment shown in FIGS. 5-6. Referring to FIGS. 5-6, the semiconductor apparatus according to example embodiments may include a substrate region 550, a first row of individual active regions 511, 512, and 513, a second row of individual active regions 521, 522, and 523, a third row of individual active regions 531, 532, and 533, and a gate pattern architecture 560. The first row of individual active regions 511, 512, and 513, the second row of individual active regions 521, 522, and 523, and the third row of individual active regions 531, 532, and 533 may be in the same configuration as the active regions of example embodiments according to FIGS. 2-3, and thus detailed descriptions thereof are omitted.

Example embodiments according to FIGS. 2-4 may include four column gate electrodes 2621, 2622, 2623 and 2624, where the column gate electrodes may be adjacent to active regions and/or in every column space between active regions. In example embodiments according to FIGS. 5-6, the gate pattern architecture 560 may include an array gate electrode 561 and two column gate electrodes 5621 and 5622, where the column gate electrodes may be adjacent to active regions and/or in every second column space between active regions. The column gate electrodes 5621 and 5622, may be on the side surfaces of the individual active regions. A gate insulation layer may be interposed between the column gate electrodes and the side surfaces. The structure shown throughout FIGS. 2-4 may be referred as a double- gate architecture, and the structure shown throughout FIGS. 5-7 may be referred as a single-gate architecture. Although FIGS. 1-7 disclose example embodiments including the gate pattern architecture 160 and/or 560, example embodiments are not limited thereto. For example, a semiconductor apparatus according to example embodiments may not include a gate pattern architecture. Where example embodiments do not include a gate pattern architecture, a pattern other than a gate pattern architecture may be in active regions and first and second impurity doped regions. Thus, various semiconductor apparatuses may be realized.

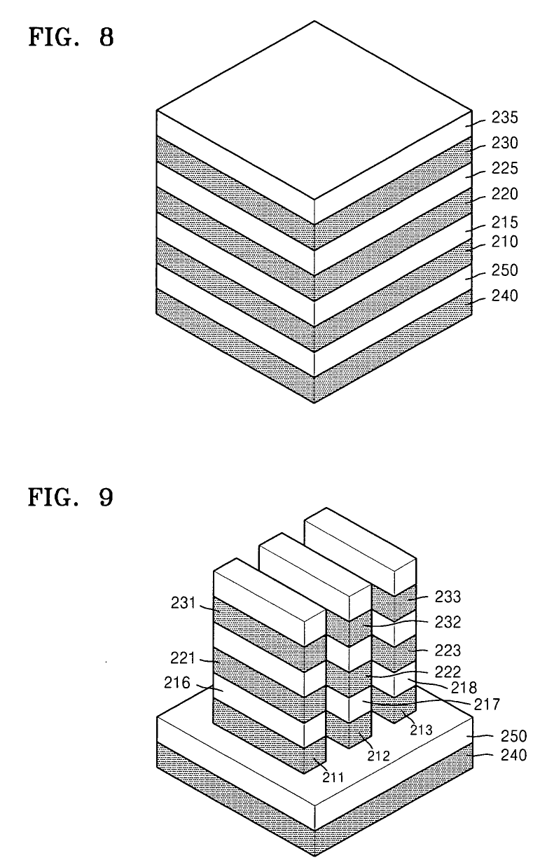

FIGS. 8-13 are perspective views of a method of fabricating a semiconductor apparatus according to an example embodiment. Referring to FIG. 8, a box region 250 may be formed on a substrate region 240, and first layers 210, 220, and 230 and second layers 215, 225, and 235 may be alternately formed on the box region 250. The first layers 210, 220, and 230, will now be called insulating layers and the second layers 215, 225, and 235 will now be called active layers for explanatory purposes, although the layers are not so limited. The operation shown in FIG. 8 may be omitted by using a wafer having a multi-SOI layer.

Referring to FIG. 9, the insulating layers 210, 220, and 230 and the active layers 215, 225, and 235 may be patterned. FIG. 9 shows that the insulating layers 210, 220, and 230 and the active layers 215, 225, and 235 may each be divided into three columns and three rows forming an active region array of individual insulating regions and individual active regions. For example, the insulating layer 210 may be divided into individual insulating regions 211, 212, and 213, corresponding to a first row and first through third columns and the active layer 215 may be divided into individual active regions 216, 217, and 218, corresponding to a first row and first through third columns. However, the number of regions is not so limited; the insulating layers 210, 220, and 230 and the active layers 215, 225, and 235 may be divided into any number of regions.

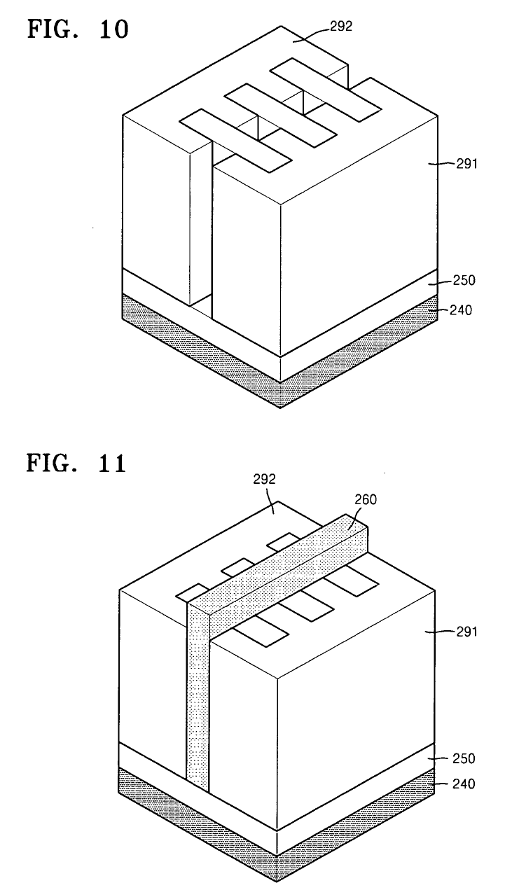

Referring to FIG. 10, an array insulation layer (e.g., a layer made of an oxide) may be formed on the active region array including the divided insulating layers 210, 220, and 230, and the divided active layers 215, 225, and 235. The array insulation layer may completely envelop or surround the divided insulating layers 210, 220, and 230, and the divided active layers 215, 225, and 235. The array insulation layer may be patterned to partially expose side surfaces of the divided insulating layers 210, 220, and 230, and the divided active layers 215, 225, and 235. The patterning process may divide the insulation material into array insulation regions 291 and 292. Referring to FIG. 11, the gate pattern architecture 260 may be formed vertically in a space between the array insulation regions 291 and 292 and horizontally above the active region array including the divided insulation layers 210, 220, and 230 and the divided active layers 215, 225, and 235. The gate pattern architecture 260 may include column gate electrodes that may be on the side surfaces of the individual active regions. A gate insulation layer may be interposed between the column gate electrodes and the side surfaces.

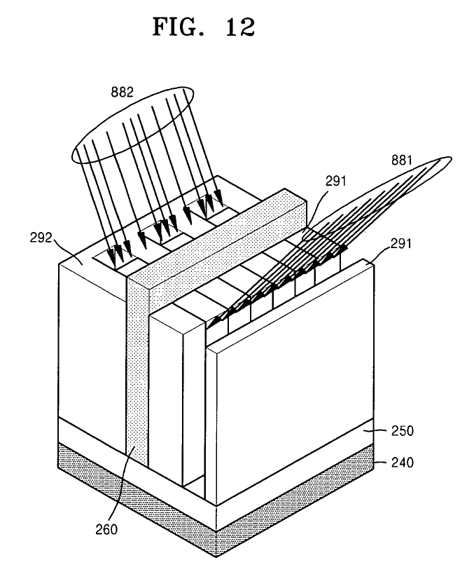

Referring to FIG. 12, the array insulation regions 291 and 292 may be patterned to expose the first and second ends of the individual active regions of the active layers 215, 225, and 235. First impurity doped regions and second impurity doped regions may be formed in the first and second ends of the individual active regions of the active layers 215, 225, and 235. The first impurity doped regions and the second impurity doped regions may be formed, for example, by implanting impurities using low energy at a low angle of incidence from sides of the active layers 215, 225, and 235. Reference numbers 881 and 882 shown in FIG. 12 are example low angle of incidence impurity paths during implantation at a low angle of incidence from sides of the active regions.

According to paths 881 and 882, the horizontal lengths of the first impurity doped regions and the second impurity doped regions may be greater for lower vertical positions along the active regions 215, 225, and 235, such that cross sectional shapes of the first and second impurity doped regions taken through a vertical plane parallel to the rows of the array of active regions are trapezoidal and/or triangular. The impurity density in the active regions 215, 225, and 235 may be uniform in the vertical direction. The ratio of maximum impurity distribution with respect to minimum impurity distribution may be less than or equal to 10:1 in the vertical direction. An interval (e.g., distance) between the first and second impurity doped regions may be equal to or greater than 2.0 F, where F is the minimum resolvable line width of a the active region array.

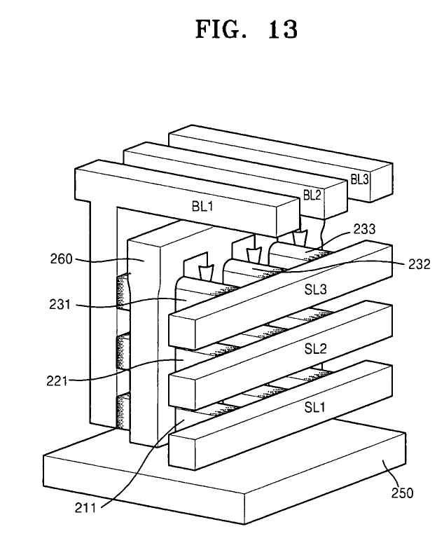

FIG. 13 is a perspective view of the interior of a semiconductor apparatus according to an example embodiment that is fabricated by the method of fabricating a semiconductor apparatus shown in FIGS. 8-12. Three layers of individual active regions may be simultaneously formed and impurity doped regions of the three layers of active regions may be simultaneously formed. Thus, a semiconductor apparatus having three layers may be fabricated by a number of operations that may be about the same as the number of operations for manufacturing a semiconductor apparatus having one layer.

Although a method of fabricating a semiconductor apparatus according to example embodiments has been described using three layers and/or three rows, the number of layers and/or rows formed may be any number. Methods of fabricating a semiconductor apparatus according to example embodiments may have about the same number of operations regardless of the number of layers and/or rows to be formed. Therefore, the number of operations for fabricating a semiconductor apparatus having a plurality of layers and/or rows may be about the same as the number of operations for fabricating a semiconductor apparatus having one layer and/or row.

The semiconductor apparatus according to the example embodiment shown in FIGS. 5-7 may differ from the semiconductor apparatus according to the example embodiment shown in FIGS. 2-4, in that the semiconductor apparatus according to the example embodiment shown in FIGS. 5-7 may have a single-gate structure and the semiconductor apparatus according to the example embodiment shown in FIGS. 2-4 may have a double-gate structure. Thus, the semiconductor apparatus according to the example embodiment shown in FIGS. 5-7 may be fabricated according to the method of fabricating a semiconductor apparatus according to the example embodiment shown in FIGS. 2-4, except that the gate pattern architecture may be formed differently.

While example embodiments have been particularly shown and described, it will be understood by one of ordinary skill in the art that variations in form and detail may be made therein without departing from the spirit and scope of the claims.

What is claimed is:

1. A semiconductor apparatus comprising:
an array of active regions including individual active regions arranged in a plurality of rows and a plurality of columns, the active regions being separated from each other and extending in parallel in a same direction such that there are row spaces between the active regions arranged in each row and there are column spaces between the active regions arranged in each column, each individual active region including a first impurity doped region at a first end and a second impurity doped region at a second end, where the first end and the second end are opposite to each other.

2. The semiconductor apparatus of claim 1, further comprising:
a gate pattern architecture including one or more column gate electrodes connected to one or more array gate electrodes, wherein
each column gate electrode extends vertically along an associated column space,
each array gate electrode extends parallel to the plurality of rows, and
the gate pattern architecture is formed as a single body.

3. The semiconductor apparatus of claim 2, wherein each column space has an associated one of the column gate electrodes.

4. The semiconductor apparatus of claim 2, wherein at least one of the column spaces does not include one of the column gate electrodes.

5. The semiconductor apparatus of claim 2, wherein
the first and second impurity doped regions are shallow doped regions, and
the first and second impurity doped regions and the gate pattern architecture do not overlap.

6. The semiconductor apparatus of claim 2, further comprising:
a first source line connected to the first impurity doped regions of a first row of the plurality of rows of individual active regions; and
a second source line connected to the first impurity doped regions of a second row of the plurality of rows of individual active regions.

7. The semiconductor apparatus of claim 2, further comprising:
a first bitline connected to the second impurity doped regions of a first column of the plurality of columns of individual active regions; and
a second bitline connected to the second impurity doped regions of a second column of the plurality of columns of individual active regions.

8. The semiconductor apparatus of claim 2, wherein the array comprises:
n rows of active regions arranged vertically, where n is a natural number equal to or greater than 3; and
j columns of active regions arranged horizontally, where j is a natural number equal to or greater than 3.

9. The semiconductor apparatus of claim 8, wherein horizontal lengths of the first and second impurity doped regions are shorter than vertical lengths of the first and second impurity doped regions.

10. The semiconductor apparatus of claim 9, wherein the horizontal lengths of the first and second impurity doped regions increase for lower vertical positions along the first and second impurity doped regions.

11. The semiconductor apparatus of claim 10, wherein
cross sectional shapes of the first and second impurity doped regions are one of (1) trapezoids of which the upper horizontal lengths are less than the lower horizontal lengths, and (2) triangles of which the horizontal length increases for lower portions thereof, and
the cross sectional shapes are taken through a vertical plane parallel to the rows of the array of active regions.

12. The semiconductor apparatus of claim 8, wherein the first and second impurity doped regions have one of (1) uniform impurity density along the vertical axis and (2) distribution of impurities along the vertical axis is a ratio of maximum impurity distribution with respect to minimum impurity distribution of less than or equal to 10:1.

13. The semiconductor apparatus of claim 1, wherein an interval between the first and second impurity doped regions is equal to or greater than 2.0 F.

14. A method of fabricating a semiconductor apparatus, the method comprising:
dividing an alternately stacked plurality of insulating layers and plurality of active layers into an array of active regions including individual active regions formed in a plurality of rows and a plurality of columns such that there are column spaces separating the plurality of columns, the individual active regions extending in parallel in a same direction, each active region having side surfaces, first end surfaces, and second end surfaces, the first end surfaces opposite the second end surfaces;
encapsulating the array of active regions with an array insulation layer;
partially patterning the array insulation layer to expose the side surfaces;
forming a gate pattern architecture including one or more column gate electrodes and one or more array gate electrodes, each of the column gate electrodes associated with at least one of the plurality of columns and formed on one or more of the side surfaces, and the array gate electrodes formed parallel to the plurality of rows;
partially patterning the array insulation layer to expose the first and second end surfaces; and
forming first and second impurity doped regions at the first and second end surfaces.

15. The method of claim 14, wherein the alternately stacked plurality of insulating layers and plurality of active layers are part of a wafer having a multi-SOI layer.

16. The method of claim 14, wherein the forming first and second impurity doped regions step comprises:
implanting impurities using low energy at a low angle of incidence from the end surfaces.

17. The method of claim 16, wherein
the dividing an alternately stacked plurality of insulating layers and plurality of active layers into an array of active regions including individual active regions formed in a plurality of rows and a plurality of columns step includes forming the plurality of columns to extend vertically and the plurality of rows to extend horizontally,
the forming first and second impurity doped regions step and the forming a gate pattern architecture step include forming the first and second impurity doped regions so that they do not overlap the gate pattern architecture, and
the forming first and second impurity doped regions step includes forming horizontal lengths of the first and second impurity doped regions shorter than vertical lengths of the first and second impurity doped regions.

18. The method of claim 17, wherein the forming first and second impurity doped regions step includes forming horizontal lengths of the first and second impurity doped regions to increase in length at lower vertical positions.

19. The method of claim 17, wherein the forming the first and second impurity doped regions step includes forming the first and second impurity doped regions to include one of: (1) uniform impurity density along the vertical axis, and (2) distribution of impurities along the vertical axis is a ratio of maximum impurity distribution with respect to minimum impurity distribution of less than or equal to 10:1.

20. The method of claim 14, wherein the forming a gate pattern architecture step includes forming one of the column gate electrodes for each of the plurality of columns.

21. The method of claim 14, wherein the forming a gate pattern architecture step includes forming one of the column gate electrodes for fewer than all of the plurality of columns.

22. The method of claim 14, further comprising:
forming a gate oxide interposed between the column gate electrodes and the side surfaces.

23. The method of claim 14, further comprising:
forming a plurality of source lines parallel to the plurality of rows and connected to the first end surfaces; and
forming a plurality of bitlines parallel to the plurality of columns and connected to the second end surfaces.
